(19) United States
(12) Patent Application Publication
(10) Pub. No.: US 2014/0182875 A1
(43) Pub. Date: Jul. 3, 2014

(54) CASE FOR AN ELECTRONIC DEVICE

(71) Applicants: MARK SPRENGER, Folsom, CA (US); PAUL GWIN, Orangevale, CA (US)

(72) Inventors: MARK SPRENGER, Folsom, CA (US); PAUL GWIN, Orangevale, CA (US)

(21) Appl. No.: 13/730,574

(22) Filed: Dec. 28, 2012

(51) Int. Cl. B29C 65/70; H05K 5/02; B29C 45/14

(52) U.S. Cl. CPC B29C 65/70; B29C 45/14008; H05K 5/02
USPC 174/50; 156/196

(57) ABSTRACT

A case for a computing device and method for generating the case are described. The method includes heating a sheet above a melting temperature of a polymer. The sheet includes composite strands impregnated with a polymer. The sheet and a multi-layer film are inserted in a mold. The sheet and multi-layer film are molded in a single mold cycle.

### TECHNICAL FIELD

This disclosure relates generally to a case for an electronic device and more specifically, but not exclusively, to manufacturing an electronic device case by molding polymer films in combination with a polymer-fiber chassis.

### BACKGROUND ART

Cases for light, thin electronic devices tend to be flimsy and cosmetically generic. One challenge in manufacturing electronic device cases is that packaging constraints limit the ways the cases can be made rigid. In terms of cosmetics, many electronic device cases, such as laptops and smartphones, are sold in a limited number of solid colors. Thus, lighter and thinner systems constrain structural and industrial designs of cases. As a result, the user experience with respect to the aesthetics of the cases may suffer. In the competitive field of consumer electronics, for example, case designs may be the deciding factor for many customers. Thus, limits in case design can limit consumer choice. Further, limits in possible case designs may limit the ways that consumers can enjoy and use their various electronic devices.

### BRIEF DESCRIPTION OF THE DRAWING

FIG. 1 is a schematic diagram of a system for generating an electronic device case in accordance with embodiments;

FIGS. 2A, 2B are side cross-sectional views of the layers of an electronic device case, in accordance with embodiments;

FIG. 3 is schematic of a system for generating a multi-layer film, in accordance with embodiments;

FIGS. 4A and 4B are schematics of systems for generating the polymer-fabric sheet, in accordance with embodiments; and

FIG. 5 is a process flow diagram 500 showing a method for manufacturing an electronic device case in accordance with embodiments.

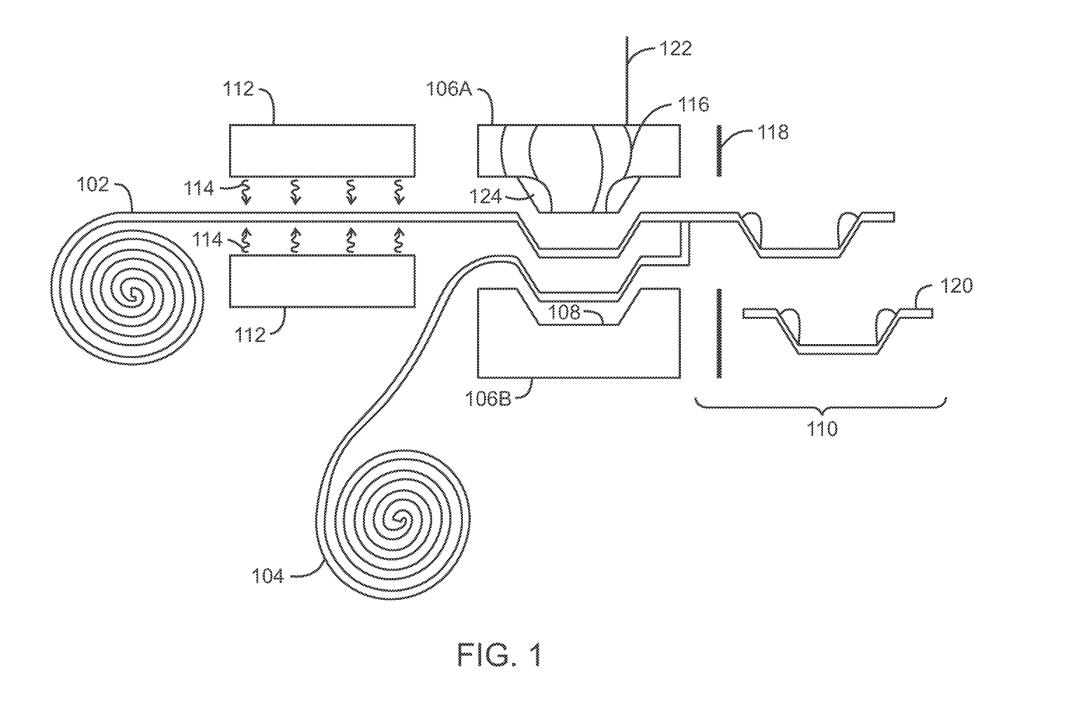

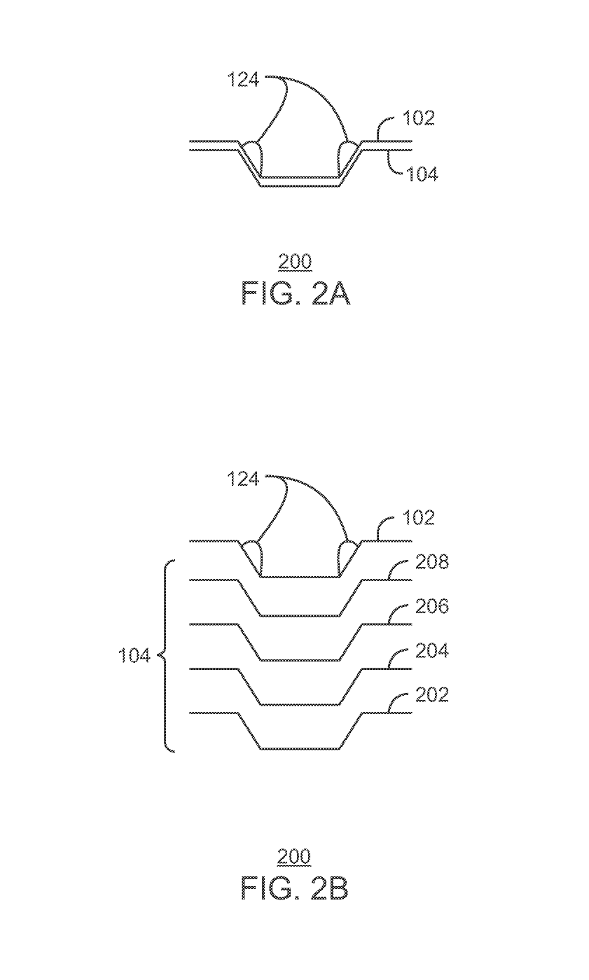

The same numbers are used throughout the disclosure and the figures to reference like components and features. Numbers in the 100 series refer to features originally found in FIG. 1; numbers in the 200 series refer to features originally found in FIG. 2; and so on.

### DESCRIPTION OF THE EMBODIMENTS

In the following description and claims, an embodiment is an implementation or example. Reference in the specification to “an embodiment,” “one embodiment,” “some embodiments,” “various embodiments,” or “other embodiments” means that a particular feature, structure, or characteristic described in connection with the embodiments is included in at least some embodiments, but not necessarily all embodiments, of the present techniques. The various appearances of “an embodiment,” “one embodiment,” or “some embodiments” are not necessarily all referring to the same embodiments. Elements or aspects from an embodiment can be combined with elements or aspects of another embodiment.

Not all components, features, structures, characteristics, etc. described and illustrated herein need be included in a particular embodiment or embodiments. If the specification states a component, feature, structure, or characteristic “may”, “might”, “can” or “could” be included, for example, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

It is to be noted that, although some embodiments have been described in reference to particular implementations, other implementations are possible according to some embodiments. Additionally, the arrangement and/or order of circuit elements or other features illustrated in the drawings or described herein need not be arranged in the particular way illustrated and described. Many other arrangements are possible according to some embodiments.

In each figure, elements may each have a same reference number or a different reference number to suggest that the elements represented could be different or similar. However, an element may be flexible enough to have different implementations and work with some or all of the systems shown or described herein. The various elements shown in the figures may be the same or different. Which one is referred to as a first element and which is called a second element is arbitrary.

Cases for electronic devices, such as laptops and smartphones may be made from a carbon fiber chassis that is coated in one or more polymer films. The carbon fiber chassis is made from a sheet that combines a fiber fabric or mesh with thermoplastic or thermoset polymers. This sheet is then molded into the shape of the chassis. The polymer films provide aesthetics, such as color. The polymer films may also provide some scratch and dent-resistance.

Light, resilient cases for electronic devices typically include a polymer-fiber in a resin matrix chassis covered in various cosmetic or protective films. The polymer-fiber chassis may be generated using one of various thermoforming or compression molding techniques. Thermoforming is the process of forming a polymer chassis through the use of heat, a metal die, and either a bladder bag or vacuum assist. Any thermoplastic or thermoset resin that can be processed into a sheet can also be thermoformed. However, if the heat exceeds the hot strength capabilities of the polymer, the polymer material loses the ability to support itself. Thermoforming techniques include, but are not limited to, vacuum, drape, pressure, and matched-mold thermoforming.

Compression molding is the process of forming a polymer chassis by compressing the polymer fiber and films between two matched metal dies. The compression generates pressure within the mold cavity, forcing the polymer matrix into the shape of the chassis mold.

FIG. 1 is a block diagram of a system 100 for generating an electronic device case in accordance with embodiments described herein. The system 100 includes a polymer- fabric sheet 102, a multi-layer film 104, a mold top 106A, and a mold bottom 1066, among other units. In some embodiments, the polymer-fabric sheet 102 can include carbon fibers, glass fibers, or higher temperature polymer fibers, among others. In some embodiments, the multi-layer film 104 can include any number of suitable films. The multi-layer film 104 is described in greater detail below in relation to FIGS. 2A and 2B. The mold bottom 106B includes a surface 108. In some embodiments, the polymer-fabric sheet 102 and the multi-layer film 104 are pressed against the surface 108 of the mold bottom 106B during the molding process. The system 100 also includes one or more downstream stations 110 for post-molding processes, such as cooling, cutting, or molding other features.

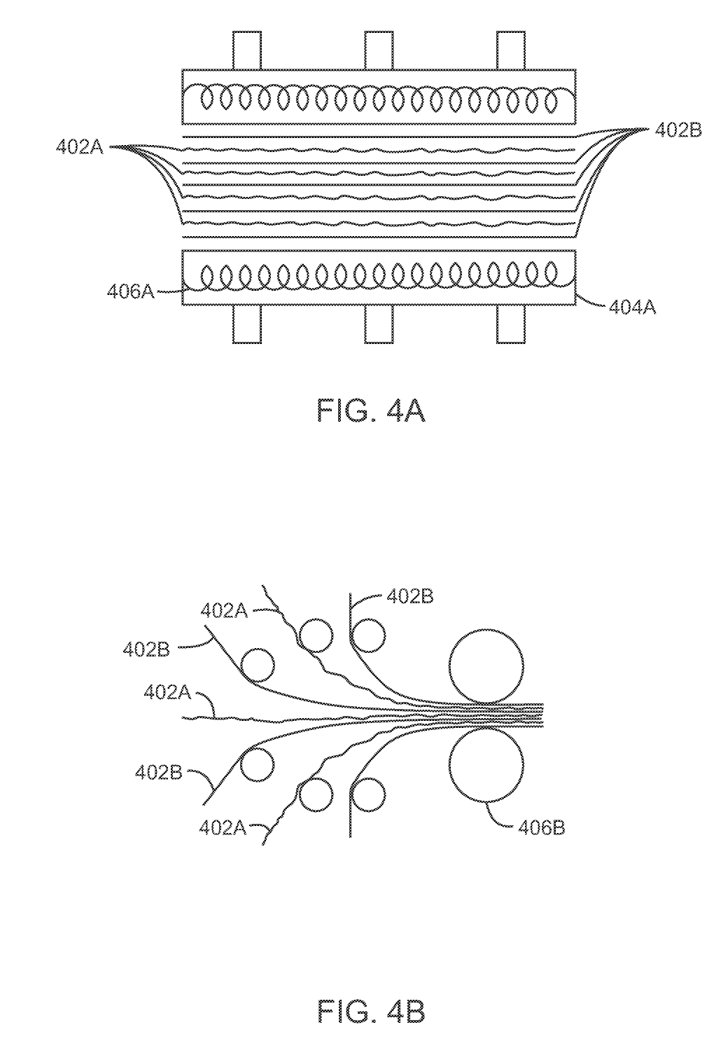

The polymer-fabric sheet 102 includes a fiber fabric that is embedded in a polymer matrix. The specified polymer holds the fabric together and contributes useful properties, such as tensile strength and elastic modulus. Tensile strength represents the maximum amount of tensile stress that a material can take without breaking. The elastic modulus represents the elasticity, or alternatively, stiffness, of the material. The polymer-fabric sheet 102 is described in greater detail with respect to FIGS. 4A and 4B.

Heat trays 112 radiate infrared energy 114, heating the polymer-fabric sheet 102 beyond a softening point, e.g., the glass transition temperature or the melting temperature, depending on the polymer. The heated polymer-fabric sheet 102 is then placed between the mold top 104A and the mold bottom 104B. The mold is closed on the sheet, and pressure is exerted through ports 116 in the mold top 106A to conform the polymer-fabric sheet 102 and the multi-layer film 104 to the mold, for example, the mold bottom 106B. At a downstream station, a cutting tool 118 can be used to cut the electronic device case 120 formed from the polymer-fabric sheet 102 and the multi-layer film 104.

In some embodiments, the multi-layer film 104 includes an adhesive layer that attaches the polymer-fabric sheet 102 to the multi-layer film 104 during the molding process. The adhesive layer enhances adhesion between the polymer matrix and the multi-layer film when an incompatibility exists between the matrix and film. In one embodiment, injection molding can be used to create backside geometry, such as bosses 124 in the electronic device case 120 in a single molding process. An injection molding gate 122 in the mold top 106A may be opened after the chassis is formed, and the polymer for the backside geometry is injected into the mold.

Bosses can refer to a feature attached or molded to the electronic device case 120. In some embodiments, bosses 124 can be designed to accept screws, or any other type of fastener, among others. Bosses can also be, or inserts can be molded into the composite in a single operation by insert molding. These bosses can also be formed by compression molding, where the backside (or front side) of the mold have geometry which protrudes out of the laminate thickness.

In one embodiment, the polymer in the polymer-fabric sheet 102 can be squeezed with the mold top 106A and the mold bottom 106B to form bosses 124. In one embodiment, the mold top 106A can be replaced with a new mold top, which can allow the bosses 124 to be formed in the electronic device case 120. For example, the new mold top may allow the bosses 124 to be formed in the electronic device case 120 using injection molding.

FIGS. 2A, 2B are side cross-sectional views of the layers of an electronic device case, in accordance with embodiments. FIG. 2A illustrates the polymer-fabric sheet 102, the multi-layer film 104, and bosses 124. In some examples, the multi-layer film 104 can be a decorative film that adheres to the polymer-fabric sheet 102. In some embodiments, the bosses 124 can be formed as the polymer-fabric sheet 102 is attached to the multi-layer film 104 in a single molding process.

FIG. 2B illustrates the polymer-fabric sheet 102, the various layers of the multi-layer film 104, and bosses 124. In some embodiments, the multi-layer film 104 includes a protective layer 202 that is a scratch resistant film, a clear film 204, a color coat film 206, and an adhesive layer 208. In one embodiment, any combination of films can be included in the multi-layer film 104 to provide for a desired look and texture. In some examples, the multi-layer film 104 can be flexible, textured, or a solid color. Additionally, the multi-layer film 104 can have a metallic appearance, a chrome appearance, a brushed metal appearance, a wood-grain appearance, and the multi-layer film 104 can include symbols and graphics. Also the multi-layer layer film may be optically clear to allow the polymer fabric to show through. The fabric may have a customized design woven into it. This design could be basic fabric such as plain, satin or twill weave, or any number of standard fabric weaves common in industry but may also include text, logos, or other customizable designs.

In some embodiments, the multi-layer film 104 can include amorphous thermoplastic films, such as ASA/PC®, Lexan®, Acrylite®, Fluorex®, thermoset plastics, or PMMA®, among others. In one embodiment, the multi-layer film comprises a temperature-resistant polymer. In some examples, the temperature resistant polymer may include polyamide, polyimide, polycarbonate, or a multi-layer structure, or a blend thereof. In some embodiments, the degradation temperature of the temperature-resistant polymer is above the melting temperature of the polymer-fabric sheet 102.

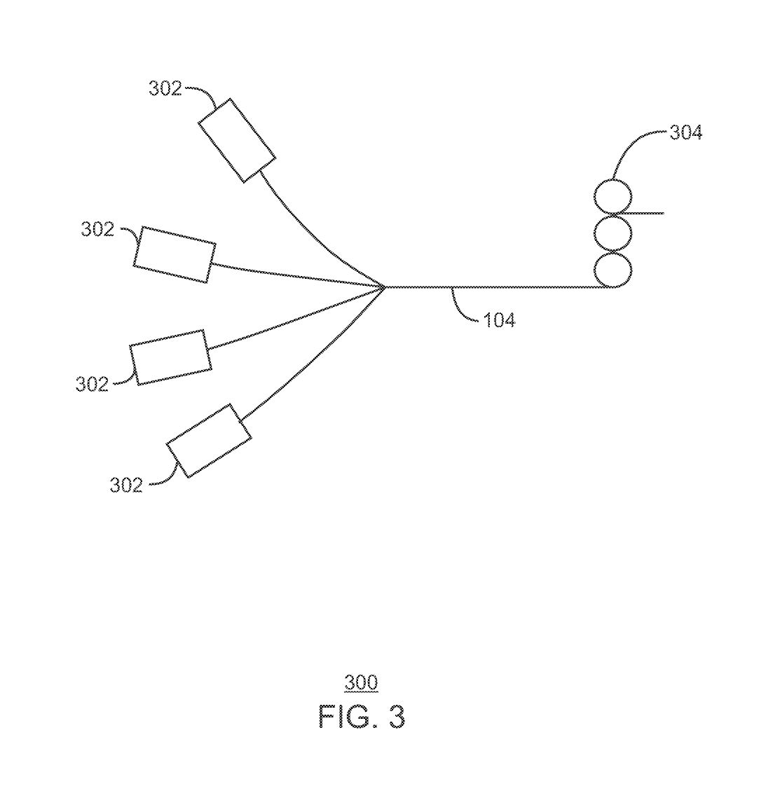

FIG. 3 is schematic of a system for generating a multi-layer film, in accordance with embodiments. The system 300 can include any suitable number of extruders 302. In some embodiments, each extruder 302 can include plastic pellets comprised of thermoplastic, such as polyamide, polyimide, polycarbonate, styrenics, acrylic polymers, or any blends thereof, among others. In some embodiments, each extruder 302 can produce a viscous melt, which can be formed into a layered structure in a multi-layer film die 304 with the viscous melts from additional extruders 302 to produce the multi-layer film 104. After extrusion, a roller stack 306 can be used to polish the surface of the multi-layer film 104.

FIGS. 4A and 4B are schematics of systems for generating the polymer-fabric sheet. In system FIG. 4A, the structure of the polymer-fabric sheet is formed by laying fabric strips 402A between thermoplastic sheets 402B to form the final structure. A hydraulic press 404A, containing a heating coil 406A, may heat the fabric strips 402A and the thermoplastic sheets 402B beyond the melting temperature. While the polymer is still a viscous melt, the hydraulic press 404A compresses the stack into a polymer fiber sheet 402.

The fabric strips 402A are made from composite strands of fiber. The pre-impregnated fiber may be made from at least one of carbon fibers, aramid fibers, glass fibers, other synthetic or organic fibers, or a combination of two or more fibers. The composite strands may be woven or unwoven. Weaving patterns for the fabrics may include, but are not limited to, plain, twill, satin, and basket. Alternatively, weaves may be specific to the material, e.g., a carbon fiber weave. To form the polymer-fabric sheet 402, the thermoplastic sheets 402B may be made from thermoplastic resins such as polyamide, polyphenylene sulfide (PPS), acrylonitrile-butadiene-styrene (ABS), polycarbonate (PC), poly-ether-ether-ketone (PEEK), other thermoplastic resins, blends, or composites thereof. Alternatively, a thermoset polymer may be used. Thermoset polymers may include epoxies, acrylates, and other resins that may be thermally or chemically cross-linked.

As shown in FIG. 4B, the polymer-fabric sheet 402 may be made in a continuous fashion. In this technique, fabric sheets 402B are fed in tandem with sheets of a thermoplastic film 404B of the specified polymer. These are fed into heated rollers 406A and 406B, which embed the fabric sheets 402B in the specified polymer to generate the polymer fabric mat.

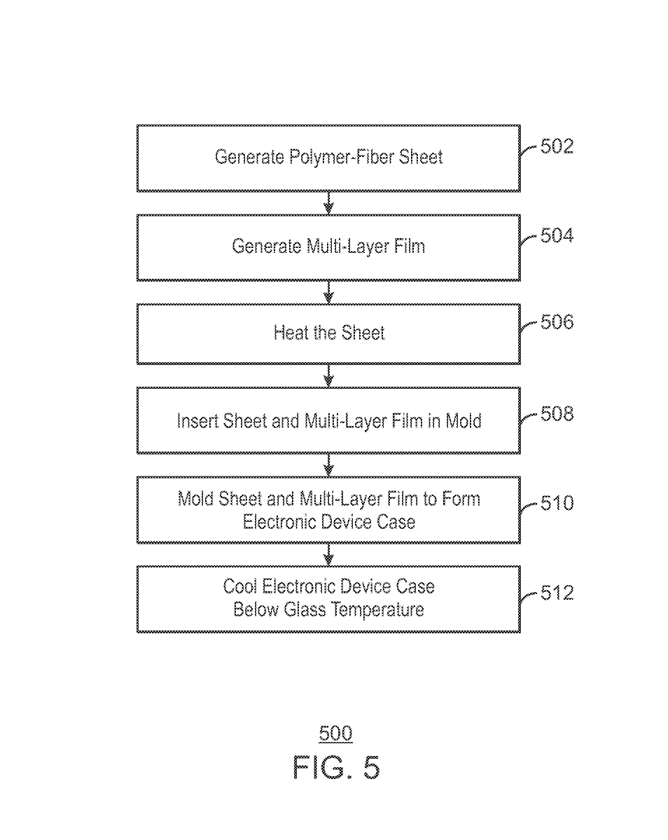

FIG. 5 is a process flow diagram 500 showing a method for manufacturing an electronic device case in accordance with embodiments. At block 502, a polymer-fiber sheet, e.g., polymer-fabric sheet 102, is generated. The polymer-fiber sheet may be cut to size before molding, or may be continuously provided from a roll of the fabric reinforced polymer composite.

At block 504, a multi-layer film, such as the multi-layer film 104 of FIG. 1, is generated. As discussed above, the multi-layer film 104 can include any suitable number of films. In some embodiments, the films of the multi-layer film 104 can be attached with an adhesive layer to form the multi-layer film 104. Alternatively, the films of the multi-layer film 104 are thermally or chemically cross-linked to form the multi-layer film 104.

At block 506, the polymer-fiber sheet is heated sufficiently to soften the polymer-fiber sheet, e.g. above the melting temperature of the sheet's polymer, Tₘ. The heat may be provided by a radiation oven, convection oven, or contact with a heated plate. In one embodiment, the heated polymer-fabric sheet is pre-stretched to control the thickness. At block 508, the polymer-fiber sheet and the multi-layer film are placed in a matched metal die, e.g., mold top 106A and mold bottom 106B, as described with respect to FIG. 1. It is noted that other mold arrangements are possible, and not limited to those described with respect to FIG. 1.

At block 510, the polymer-fiber sheet and the multi-layer film are molded into the specific shape of the electronic device case, such as 120 of FIG. 1. At block 512, the formed electronic device case is cooled to below the glass temperature, T_{g}, and the formed electronic device case is cut from the sheet. In one embodiment, the formed electronic device case is trimmed using dies in the mold or at a downstream station 110.

It is to be understood that specifics in the aforementioned examples may be used anywhere in one or more embodiments. For instance, all optional features of the computing device described above may also be implemented with respect to either of the methods or the computer-readable medium described herein. Furthermore, although flow diagrams and/or state diagrams may have been used herein to describe embodiments, the present techniques are not limited to those diagrams or to corresponding descriptions herein. For example, flow need not move through each illustrated box or state or in exactly the same order as illustrated and described herein.

The present techniques are not restricted to the particular details listed herein. Indeed, those skilled in the art having the benefit of this disclosure will appreciate that many other variations from the foregoing description and drawings may be made within the scope of the present techniques. Accordingly, it is the following claims including any amendments thereto that define the scope of the present techniques.

What is claimed is:

1. An electronic device case, comprising:
a polymer-fiber sheet comprising a fiber fabric embedded in a polymer matrix; and
a multi-layer film comprising a plurality of polymer films.

2. The electronic device case of claim 1, wherein the polymer-fiber sheet comprises a thermoplastic polymer or a thermoset polymer.

3. The electronic device case of claim 2, wherein the thermoplastic polymer comprises a polyamide, a polyimide, a polycarbonate, a styrenic, an acrylic polymer, or a blend thereof.

4. The electronic device case of claim 2, wherein the thermoset polymer comprises an epoxy, an acrylate, or a blend thereof.

5. The electronic device case of claim 1, wherein bosses are adhered to the case.

6. The electronic device case of claim 1, wherein the melting temperature of a material of the polymer matrix is below a degradation temperature of the multi-layer film.

7. The electronic device case of claim 1, wherein the multi-layer film comprises a temperature-resistant polymer.

8. The electronic device case of claim 7, wherein the temperature-resistant polymer comprises a polyamide, a polyimide, a polycarbonate, or a blend thereof.

9. The electronic device case of claim 1, wherein the fiber fabric comprises a pre-determined design weave, wherein the pre-determined design weave comprises one of plain, satin or twill weave, or a standard fabric weave, and wherein the pre-determined design weave comprises one of text, one or more logos, or other customizable design.

10. The electronic device case of claim 1, wherein the multi-layer film comprises a scratch resistant film, a clear film, and a color coat film.

11. An electronic device comprising a case, the case comprising:
a polymer-fiber sheet comprising a fiber fabric embedded in a polymer matrix;
a multi-layer film comprising a plurality of polymer films; and
an adhesive layer disposed between the multi-layer film and the polymer-fiber sheet, wherein the adhesive layer enhances adhesion between the polymer matrix and the multi-layer film when an incompatibility exists between the polymer matrix and the multi-layer film.

12. The electronic device of claim 11, wherein the polymer films comprise a scratch resistant film and a clear film.

13. The electronic device of claim 12, wherein the fiber fabric comprises a pre-determined design weave, wherein the pre-determined design comprises one of plain, satin, or twill weave.

14. The electronic device of claim 13, wherein the pre-determined design comprises text, one or more logos, or a combination of the text and the logos.

15. The electronic device of claim 11, wherein the polymer-fiber sheet comprises a thermoplastic polymer or a thermoset polymer.

16. The electronic device of claim 15, wherein the thermoplastic polymer comprises a polyamide, a polyimide, a polycarbonate, a styrenic, an acrylic polymer, or a blend thereof.

17. The electronic device of claim 15, wherein the thermoset polymer comprises an epoxy, an acrylate, or a blend thereof.

18. The electronic device of claim 11, comprising bosses adhered to the case.

19. The electronic device of claim 11, wherein the melting temperature of a material of the polymer matrix is below a degradation temperature of the multi-layer film.

20. The electronic device of claim 11, wherein the multi-layer film comprises a temperature-resistant polymer.

21. A method for generating a case for an electronic device, comprising:
heating a sheet comprising composite strands impregnated with a polymer above a melting temperature of the polymer;
inserting the sheet and a multi-layer film in a mold; and
molding the sheet and the multi-layer film in a single mold cycle.

22. The method of claim 21 comprising generating a plurality of bosses on the case.

23. The method of claim 22, wherein generating the bosses comprises injection molding the bosses.

24. The method of claim 22, wherein generating the bosses comprises:
replacing a mold top with another mold top; and
injection molding the bosses through the other mold top.

25. The method of claim 22, wherein generating the bosses comprises injection molding the bosses through a mold top.

26. The method of claim 22, wherein generating the bosses comprises squeezing the polymer from the sheet into a mold top, and wherein the mold top comprises a geometry for the bosses.

27. The method of claim 21, wherein the multi-layer film comprises a scratch resistant film, a clear film, a color coat film, and an adhesive layer.

28. The method of claim 21, wherein the composite strands comprise a fiber fabric.

29. The method of claim 28, wherein the fiber fabric comprises a carbon fiber fabric.
